(19) United States
(12) Patent Application Publication
(10) Pub. No.: US 2025/0098378 A1
(43) Pub. Date: Mar. 20, 2025

(54) METHOD FOR MANUFACTURING OPTOELECTRONIC STRUCTURE AND A PACKAGE STRUCTURE

(71) Applicant: Advanced Semiconductor Engineering, Inc., Kaohsiung (TW)

(72) Inventors: Pei-Jung YANG, Kaohsiung (TW); Jr-Wei LIN, Kaohsiung (TW); Mei-Ju LU, Kaohsiung (TW); Chi-Han CHEN, Kaohsiung (TW)

(73) Assignee: Advanced Semiconductor Engineering, Inc., Kaohsiung (TW)

(21) Appl. No.: 18/369,107

(22) Filed: Sep. 15, 2023

(51) Int. Cl. H01L 33/58; H01L 25/075; H01L 25/16

(52) U.S. Cl. CPC H10H 20/855; H01L 25/0753; H01L 25/167; H10H 20/0363

(57) ABSTRACT

A method for manufacturing an optoelectronic structure and a package structure are provided. The method includes providing a substrate and a light source module and a photonic component over the substrate; and adjusting a lens structure to a unit specific position related to the substrate to couple an optical signal from the light source module to the photonic component.

### BACKGROUND

### 1. Technical Field

The present disclosure relates generally to a method for manufacturing an optoelectronic structure and to a package structure.

### 2. Description of the Related Art

Light source modules are normally manufactured by assembling optical elements/components by active alignment, after which the light source module is actively aligned with a photonic component to form a package. In the active alignment process, the light source module transmits an optical signal directly to the photonic component, and the optical signal received by the photonic component is monitored when the light source module continues changing position. The light source module must be turned on and moved until an optimum optical signal is monitored by the photonic component to complete the active alignment process.

### SUMMARY

In one or more arrangements, a method for manufacturing an optoelectronic structure includes providing a substrate and a light source module and a photonic component over the substrate; and adjusting a lens structure to a unit specific position related to the substrate to couple an optical signal from the light source module to the photonic component.

In one or more arrangements, a method for manufacturing an optoelectronic structure includes providing a substrate; providing a first light source module, a first photonic component, a second light source module, and a second photonic component over the substrate; actively aligning the first light source module with the first photonic component by moving a first lens structure to a first unit specific position related to the first photonic component; and actively aligning the second light source module with the second photonic component by moving a second lens structure to a second unit specific position related to the second photonic component.

In one or more arrangements, a package structure includes an optoelectronic structure. The optoelectronic structure optoelectronic structure includes a first optical component, a second optical component, and an optical alignment component configured to define an optical path between the first optical component and the second optical component. The optical alignment component is disposed at a unit specific position related to the first optical component and the second optical component.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A, FIG. 1B, FIG. 1C, FIG. 2, FIG. 3, FIG. 4, FIG. 5, FIG. 6, FIG. 7, and FIG. 8 illustrate various stages of an exemplary method for manufacturing an optoelectronic structure in accordance with some arrangements of the present disclosure.

FIG. 9, FIG. 10, FIG. 11, FIG. 12, and FIG. 13 illustrate various stages of an exemplary method for manufacturing an optoelectronic structure in accordance with some arrangements of the present disclosure.

FIG. 14A is a top view of a package structure in accordance with some arrangements of the present disclosure.

FIG. 14B is a cross-section of a portion of a package structure in accordance with some arrangements of the present disclosure.

FIG. 14C is a cross-section of a portion of a package structure in accordance with some arrangements of the present disclosure.

FIG. 15A is a top view of a package structure in accordance with some arrangements of the present disclosure.

FIG. 15B is a cross-section of a portion of a package structure in accordance with some arrangements of the present disclosure.

FIG. 16A is a top view of a package structure in accordance with some arrangements of the present disclosure.

FIG. 16B is a cross-section of a portion of a package structure in accordance with some arrangements of the present disclosure.

Common reference numerals are used throughout the drawings and the detailed description to indicate the same or similar elements.

### DETAILED DESCRIPTION

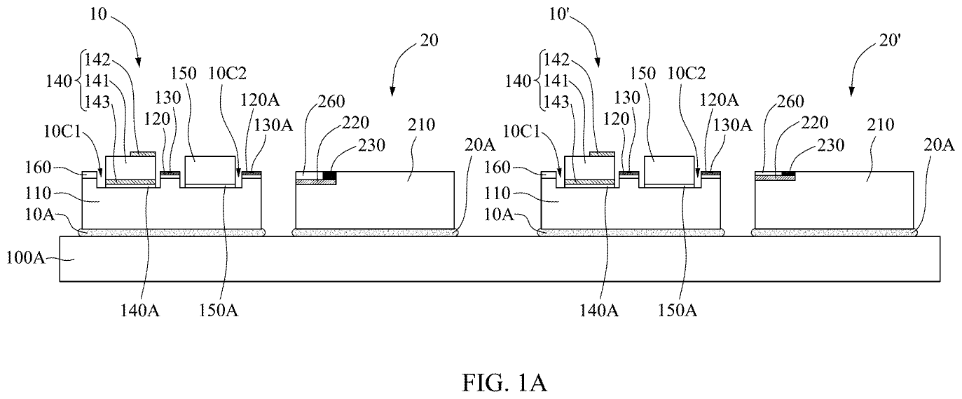

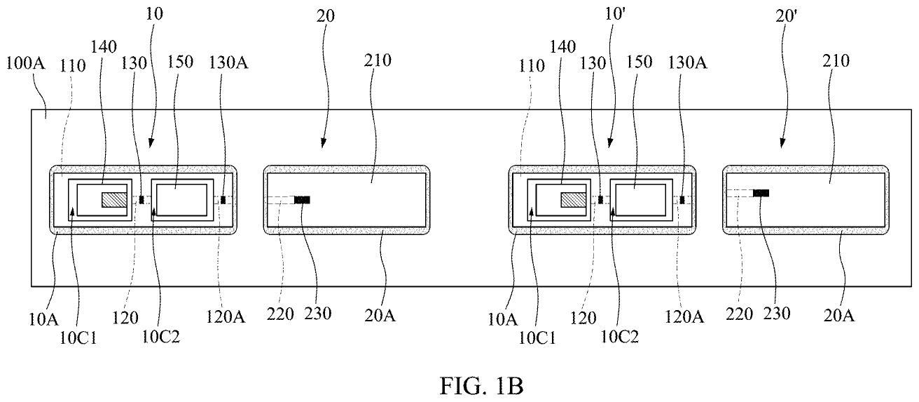

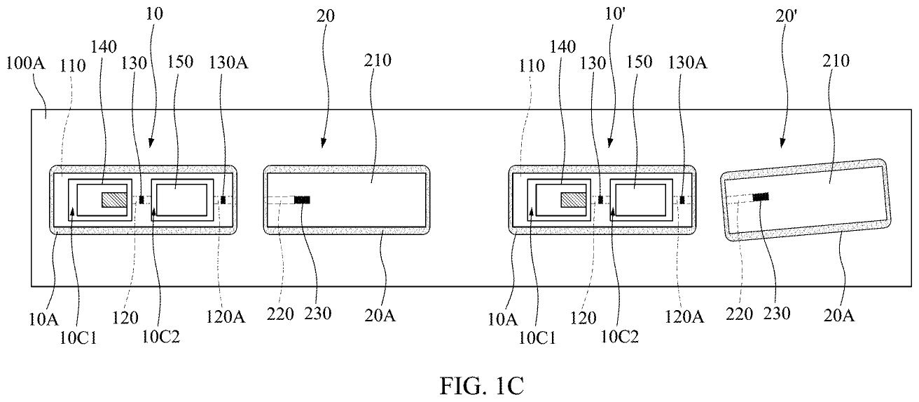

FIG. 1A, FIG. 1B, FIG. 1C FIG. 2, FIG. 3, FIG. 4, FIG. 5, FIG. 6, FIG. 7, and FIG. 8 illustrate various stages of an example of a method for manufacturing an optoelectronic structure in accordance with some arrangements of the present disclosure.

FIG. 1A and FIG. 1B, which illustrate various stages of an exemplary method for manufacturing an optoelectronic structure, are a cross-section and top view respectively of a substrate 100A and optical components which may be provided thereby. The optical components may include light source modules 10 and 10′ and photonic components 20 and 20′. The light source modules 10 and 10′ and photonic components 20 and 20′ may be provided over the substrate 100A.

In some arrangements, the light source modules 10 and 10′ and the photonic components 20 and 20′ are disposed over (e.g., affixed to) the substrate 100A. In some arrangements, the light source modules 10 and 10′ are disposed over (e.g., affixed to) the substrate 100A by adhesive elements 10A. In some arrangements, the photonic components 20 and 20′ are attached or affixed to the substrate 100A by adhesive elements 20A. In some arrangements, the light source modules 10 and 10′ are moved to the substrate 100A without turning on the light source modules 10 and 10′. In some arrangements, in the process of moving the light source modules 10 and 10′ to the substrate 100A and before the light source modules 10 and 10′ are attached or affixed to the substrate 100A, the light source modules 10 and 10′ are not turned on (i.e. not powered up), that is, no voltage is supplied to the light sources of the light source modules 10 and 10′.

In some arrangements, the light source module 10 includes a substrate layer 110, waveguides 120 and 120A, photodetectors 130 and 130A, a light source 140, an active optical element 150, and a dielectric layer 160. The substrate layer 110 may include a silicon-based layer and one or more circuit layers formed in the silicon-based layer. The circuit layers may include a driver circuit (e.g., a laser diode driver circuit). The substrate layer 110 and the dielectric layer 160 collectively define cavities 10C1 and 10C2. The waveguides 120 and 120A may be formed on the dielectric layer 160, and the photodetectors 130 and 130A may be formed over the dielectric layer 160 and optically coupled to the waveguides 120 and 120A, respectively. The photodetector 130 may be configured to detect one or more optical signals transmitted through the waveguide 120, and the photodetector 130A may be configured to detect one or more optical signals transmitted through the waveguide 120A. The dielectric layer 160 may serve as a protective layer or a passivation layer for the waveguides 120 and 120A and the photodetectors 130 and 130A. The light source 140 may be or include a laser diode. The light source 140 may include a light-emitting layer 141 and electrodes 142 and 143. The light source 140 may be adhered to a bottom of the cavity 10C1 by an adhesive layer 140A. The active optical element 150 may be adhered to a bottom of the cavity 10C2 by an adhesive layer 150A. The active optical element 150 may include an amplifier, e.g., a semiconductor optical amplifier (SOA). The active optical element 150 may be passively aligned by the waveguide 120 and/or 120A.

In some arrangements, the photonic component 20 includes a substrate layer 210, a waveguide 220, a photodetector 230, and a dielectric layer 260. The substrate layer 210 may include a silicon-based layer and one or more circuit layers formed in the silicon-based layer. The circuit layers may include a driver circuit (e.g., a photonic integrated circuit). The waveguide 220 may be formed on a portion of the substrate layer 210, and the photodetector 230 may be formed on and optically coupled to the waveguide 220. The photodetector 230 may be configured to detect and/or monitor one or more optical signals transmitted from the waveguide 220. The dielectric layer 260 may serve as a protective layer or a passivation layer for the waveguide 220 and the photodetector 230.

In some arrangements, the light source module 10′ has a structure similar to that of the light source module 10, and description thereof is omitted herefrom. In some arrangements, the photonic component 20′ has a structure similar to that of the photonic component 20, except that the thicknesses of the photodetectors 230 are different, the thicknesses of the dielectric layers 260 are different, the waveguides 220 are at different elevations, and the waveguides 220 are misaligned from a top view perspective.

Referring to FIG. 1C, which illustrates various stages of an exemplary method for manufacturing an optoelectronic structure, is a top view of the substrate 100A and optical components which may be provided thereby. In some arrangements, the photonic component 20′ may be misaligned with the light source module 10′. In some arrangements, a long side of the photonic component 20′ may be non-parallel to a long side of the light source module 10′. In some arrangements, the photonic component 20′ is rotated offset from the light source module 10′. In some arrangements, the waveguide 220 may be misaligned with the waveguide 120A. In some arrangements, the waveguide 220 may be non-parallel to the waveguide 120A. In some arrangements, the waveguide 220 is rotated offset from the waveguide 120A.

Referring to FIG. 2, the light source modules 10 and 10′ may be connected to a power supply configured to provide power to turn on the light sources 140. Probes 200 and 200′ (or terminals) of the power supply may be connected to the electrodes 142 and 143 of the light sources 140 (or the laser diodes). The photonic components 20 and 20′ may be connected to a device that is configured to receive detected and/or monitored results of optical signals from the photodetectors 230. Probes 300 and 300′ (or terminals) of the device may be connected to the photodetectors 230 of the photonic components 20 and 20′.

Referring to FIG. 3, an active alignment between the waveguide 120A of the light source module 10 and the photonic component 20 may be performed. In some arrangements, a lens 30 (also referred to as “a lens structure” or “an optical alignment component”) may be provided. In some arrangements, the lens 30 is configured to couple one or more optical signals from the waveguide 120A of the light source module 10 to the photonic component 20. In some arrangements, the lens 30 is further configured to focus light (e.g., the optical signal) emitted by the light source module 10 and direct the focused light to the waveguide 220 of the photonic component 20. In some arrangements, active alignment between the waveguide 120A of the light source module 10 and the photonic component 20 is performed using the lens 30. In some arrangements, aligning (or actively aligning) the light source module 10 with the photonic component 20 includes or is performed by moving the lens 30 to actively align the waveguide 120A with the photonic component 20. In some arrangements, the lens 30 may be adjusted to a unit specific position P1 related to the substrate 100A to couple an optical signal from the light source module 10 to the photonic component 20. In some arrangements, the active alignment includes aligning (or actively aligning) an optical path O1 between the waveguide 120A and the photonic component 20 by adjusting or moving the lens 30 to a unit specific position P1.

In some arrangements, the active alignment between the waveguide 120A of the light source module 10 and the photonic component 20 may include the following operations. In some arrangements, the optical signal passing the lens 30 and received by the photonic component 20 is monitored when adjusting or moving the lens 30. The lens 30 may be adjusted by moving the lens 30 in multiple directions (e.g., in x-axis, y-axis, z-axis, and/or any direction in three-dimensional space) to maximize or optimize the optical signal received and monitored by the photonic component 20. For example, the lens 30 may be moved to change the elevation of the lens 30 with respect to the substrate 100A, a distance between the lens 30 and the light source module 10 and/or the photonic component 20, a tilt angle of a major axis of the lens 30 with respect to a surface of the light source module 10 and/or the photonic component 20, or the like. The lens 30 may be adjusted or moved by a vacuum suction mechanism 400. In some arrangements, a planar upper surface of the lens 30 may be attached to the vacuum suction mechanism 400, and the position of the vacuum suction mechanism 400 may be adjusted to adjust the lens 30. In some arrangements, adjusting or moving the lens 30 in the active alignment process allows the lens 30 to eventually arrive at a position (e.g., the unit specific position P1) configured for optimum coupling that ensures an optimum optical alignment between the light source module 10 (e.g., the waveguide 120A) and the photonic component 20. In some arrangements, it is determined whether the lens 30 is or has arrived at the unit specific position P1 when the monitored optical signal (or the optical signal being monitored) reaches a predetermined optimization threshold. In some arrangements, the predetermined optimization threshold includes a predetermined intensity, a predetermined pattern, a predetermined intensity distribution, a predetermined signal-to-noise (S/N) ratio, or any combination thereof.

The unit specific position may be created for each individual unit (e.g., each set of components including the light source module 10, the photonic component 20, and the lens 30) according to the measured or monitored optical signal received by the photonic component 20. The unit specific positions of the lenses 30 for different sets of the light source module 10, the photonic component 20, and the lens 30 (or different individual units) manufactured may be different so that each light source module 10 is correctly or optimally aligned with each photonic component 20. That is, each unit specific position of the lens 30 may be uniquely created for each set of the light source module 10, the photonic component 20, and the lens 30 (or each individual unit).

The unit specific position P1 may be a position related to the substrate 100A, or a position related to the light source module 10 and/or the photonic component 20. The unit specific position P1 may be or include various positions, such as an elevation of the lens 30 with respect to the substrate 100A, a distance between the lens 30 and the substrate 100A, a distance between the lens 30 and the waveguide 120A, a distance between the lens 30 and the photonic component 20, a difference in elevations of the lens 30 and the waveguide 120A, a difference in elevations of the lens 30 and the photonic component 20, and any combination thereof.

In some arrangements, aligning (or actively aligning) the optical path O1 further includes adjusting or moving the lens 30 without moving positions of the light source module 10 and the photonic component 20. In some arrangements, alignment (or active alignment) of the optical path O1 is performed or started after the light source module 10 and the photonic component 20 are completely disposed over (e.g., affixed to) the substrate 100A. In some arrangements, the probes (or the terminals) 200, 200′, 300, and 300′ for the light source modules 10 and 10′ and the photonic components 20 and 20′ may be all arranged (e.g., the probes 200, 200′, 300, and 300′ are all connected to the light source modules 10 and 10′ and the photonic components 20 and 20′) when only the active alignment between the light source module 10 and the photonic component 20 is performed.

Referring to FIG. 4, after the unit specific position P1 of the lens 30 is determined, the lens 30 may be removed from the unit specific position P1. In some arrangements, the unit specific position P1 is stored in a processing unit of the device that connects to the probe 300 (or terminal). In some arrangements, an adhesive element 30A is then disposed (or positioned) adjacent to the unit specific position P1. In some arrangements, the position of the adhesive element 30A is determined according to the unit specific position P1 stored in the processing unit. The adhesive element 30A may be or include a photosensitive glue.

Referring to FIG. 5, the lens 30 may be disposed on (e.g., affixed to) the unit specific position P1. In some arrangements, the lens 30 is guided to contact or be connected to the adhesive element 30A to affix the lens 30 at the unit specific position P1 through the adhesive element 30A. In some arrangements, the lens 30 is movably disposed on (or affixed at) the unit specific position P1 through the adhesive element 30A, and then a post-alignment may be further performed. In some arrangements, a portion of the lens 30 may be inserted into the adhesive element 30A. In some arrangements, the post-alignment includes post-aligning the optical path O1 by adjusting or moving the lens 30 to the unit specific position P1 after positioning the adhesive element 30A. In some arrangements, the light source module 10 is post-actively aligned with the photonic component 20 by adjusting or moving the lens 30 related to the adhesive element 30A. After the lens 30 is moved again, the position of the lens 30 that contacts the adhesive element 30A may be slightly shifted from the exact unit specific position P1. Therefore, the post-alignment including operations similar to those for the aforesaid active alignment between the light source module 10 and the photonic component 20 may be performed to fine tune the exact position of the lens 30 to ensure an optimum optical alignment between the light source module 10 (e.g., the waveguide 120A) and the photonic component 20 through the lens 30. In some arrangements, the light source module 10 remains on during the entire process illustrated in FIGS. 3-5. In some other arrangements, another lens that is substantially the same as or identical to the lens 30 used for the active alignment illustrated in FIG. 3 may be provided to be disposed on the unit specific position P1. In some arrangements, two lenses 30 having substantially the same or identical structures may be used in the active alignment operation and disposed on the unit specific position P1, respectively.

In some arrangements, operations similar to those illustrated in FIG. 3 may be performed to actively align the light source module 10′ with the photonic component 20′ by moving the lens 30′ to actively align the waveguide 120A of the light source module 10′ with the photonic component 20′. In some arrangements, the lens 30′ may be adjusted to a unit specific position P2 related to the substrate 100A to couple an optical signal from the light source module 10′ to the photonic component 20′. In some arrangements, the active alignment includes aligning (or actively aligning) an optical path O2 between the waveguide 120A of the light source module 10′ and the photonic component 20′ by adjusting or moving the lens 30′ to a unit specific position P2. In some arrangements, actively aligning the light source module 10′ with the photonic component 20′ is performed after actively aligning the light source module 10 with the photonic component 20 is completed. The operations for actively aligning the light source module 10 with the photonic component 20 by the lens 30 are the same as or similar to the operations performed for actively aligning the light source module 10′ with the photonic component 20′ by the lens 30′ described here, and thus description thereof is omitted herefrom.

Referring to FIG. 6, operations similar to those illustrated in FIG. 4 may be performed to remove the lens 30 from the unit specific position P2 and position an adhesive element 30A′ adjacent to the unit specific position P2.

Referring to FIG. 7, operations similar to those illustrated in FIG. 5 may be performed to dispose the lens 30′ on or connect (or affix) the lens 30′ to the unit specific position P2. In some arrangements, the light source module 10′ is actively aligned with the photonic component 20′ by adjusting or moving the lens 30′ to the unit specific position P2 related to the light source module 10′ and/or the photonic component 20′. In some arrangements, the lens 30′ is movably disposed on (or affixed to) the unit specific position P2 through the adhesive element 30A′, and then the light source module 10′ is post-actively aligned with the photonic component 20′ by adjusting or moving the lens 30′ related to the adhesive element 30A′. The operations for affixing the lens 30′ to the unit specific position P2 are the same as or similar to the operations performed for affixing the lens 30 to the unit specific position P1 described here, and thus description thereof is omitted herefrom.

Referring to FIG. 8, the lens 30 may be disposed on (or permanently affixed at) the unit specific position P1, and the lens 30′ may be disposed on (or permanently affixed at) the unit specific position P2. In some arrangements, disposing (or permanently affixing) the lens 30 at the unit specific position P1 is performed in the same operation as disposing (or permanently affixing) the lens 30′ at the unit specific position P2. In some arrangements, the adhesive elements 30A and 30A′ may be cured (e.g., by UV) to attach (or permanently affix) the lenses 30 and 30′ at the unit specific positions P1 and P2, respectively, after post-aligning the optical paths O1 and O2. In some arrangements, actively aligning the light source module 10 with the photonic component 20 and actively aligning the light source module 10′ with the photonic component 20′ are performed in different operations. In some arrangements, the adhesive element 30A and the adhesive element 30A′ are cured in a same operation.

In some arrangements, a singulation operation may be performed on the substrate 100A to form a singulated structure (e.g., an optoelectronic structure 1) including the light source module 10, the photonic component 20, and the lens 30 on a substrate 100, and a singulated structure (e.g., an optoelectronic structure 1A) including the light source module 10′, the photonic component 20′, and the lens 30′ on a substrate 100′.

In some other arrangements, the adhesive elements 30A and 30A′ may be disposed on the substrate 100A before the active alignment between the light source module 10 and the photonic component 20 illustrated in FIG. 3 and the active alignment between the light source module 10′ and the photonic component 20′ illustrated in FIG. 5. In some arrangements, the lens 30 may be movably disposed on the adhesive element 30A during the active alignment operation, and the lens 30′ may be movably disposed on the adhesive element 30A′ during the active alignment operation. In some arrangements, the adhesive elements 30A and 30A′ may be cured after the active alignments of the lenses 30 and 30′.

In some other arrangements, a time duration for performing the active alignment between the light source module 10 and the photonic component 20 illustrated in FIG. 3 may at least partially overlap a time duration for performing the active alignment between the light source module 10′ and the photonic component 20′ illustrated in FIG. 5. For example, the active alignment between the light source module 10 and the photonic component 20 illustrated in FIG. 3 and the active alignment between the light source module 10′ and the photonic component 20′ illustrated in FIG. 5 may be performed using different vacuum suction mechanisms 400. For example, an operation time duration for using a first vacuum suction mechanism 400 to adjust the lens 30 may at least partially overlap an operation time duration for using a second vacuum suction mechanism 400 to adjust the lens 30′.

In some cases, a light source module includes optical elements/components that are actively aligned and is actively aligned with a photonic component by monitoring an optical signal received by the photonic component that is transmitted directly from the light source module. The light source module has to be turned on and being moved until an optimum optical signal is monitored by the photonic component to complete the active alignment process. The light source module has a relatively large volume and a relatively complex structure, and thus a relatively complicated setup is required to move the light source module with the light source module being turned on or powered up (connected to a power supply), and the pick-up head for moving the light source module requires a relatively special design in order to pick up and move the complicated and heavy module in the active alignment process.

According to some arrangements of the present disclosure, the light source module includes optical components that are passively aligned, and the light source module is then actively aligned with the photonic component by the lens (or the lens structure). Therefore, the time and the cost for actively aligning the optical components within the light source module can be reduced. In addition, the lens (or the lens structure) has a relatively simple structure, less weight, and a relatively small volume, whereby moving the lens (or the lens structure) to perform the active alignment process is easier and less time-consuming than moving the entire light source module.

In addition, according to some arrangements of the present disclosure, the light source module and the photonic component are disposed over or affixed to the substrate prior to actively aligning the light source module with the photonic component by adjusting or moving the lens (or the lens structure). Therefore, setup in the alignment process is simplified because the light source module is not moving when powered up (connected to a power supply). Moreover, since the active alignment only involves adjusting or moving the lens (or the lens structure) with a relatively simple structure, less weight, and a relatively small volume, there is no need to provide a pick-up head with a special design. For example, a common vacuum head may be used to move the lens (or the lens structure). Therefore, the processing apparatus is simplified, and the alignment setup is more flexible.

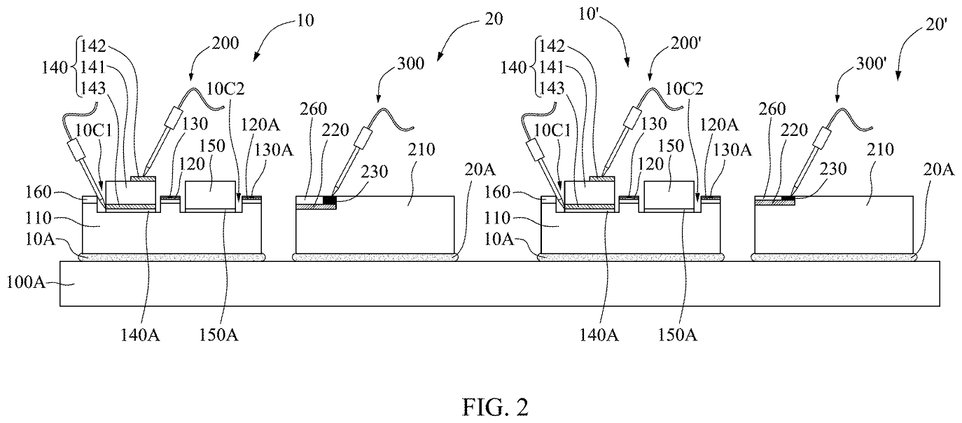

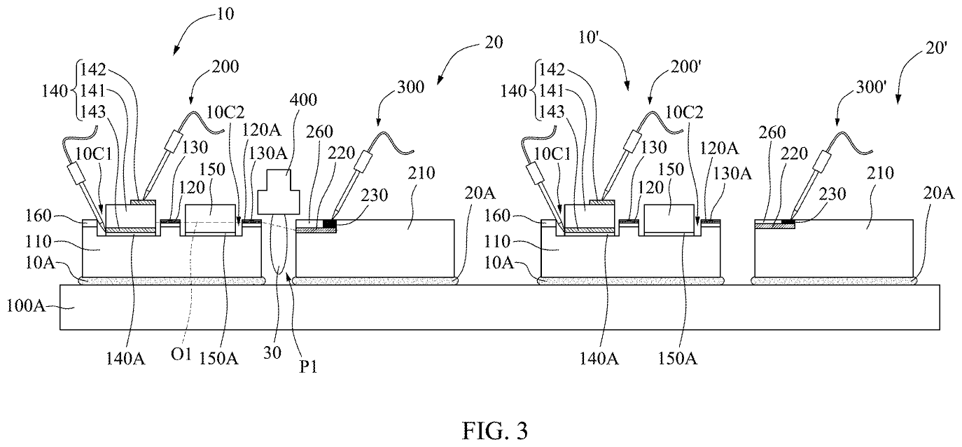

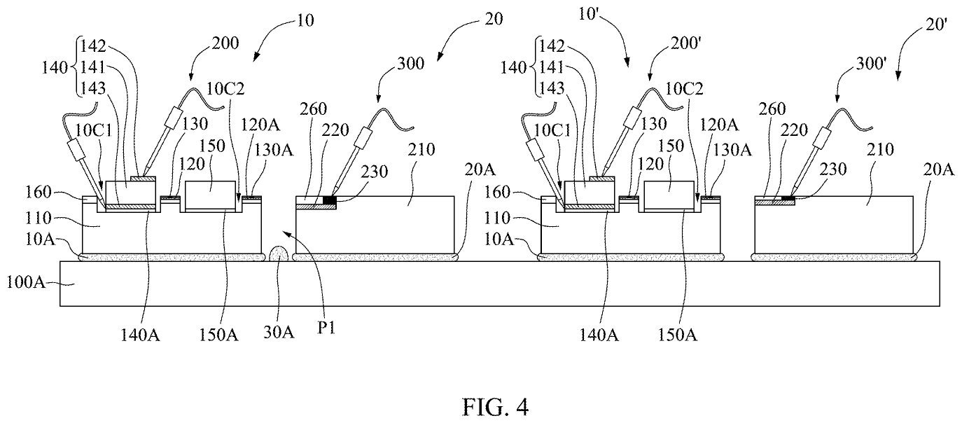

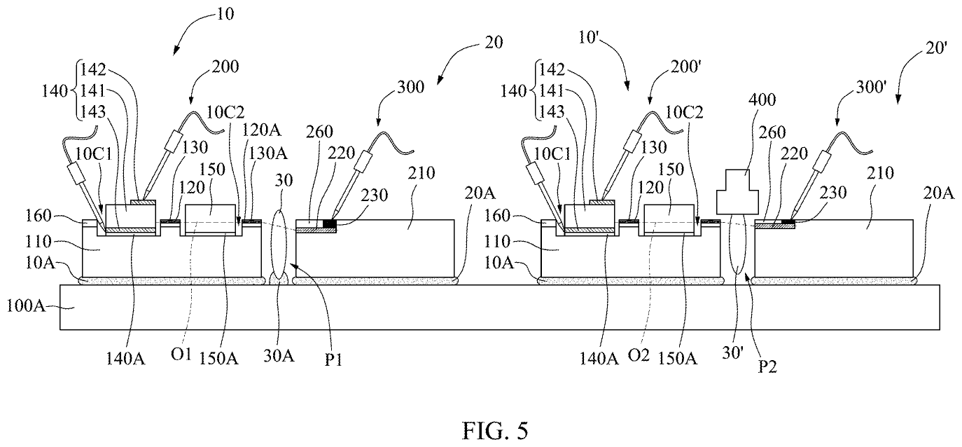

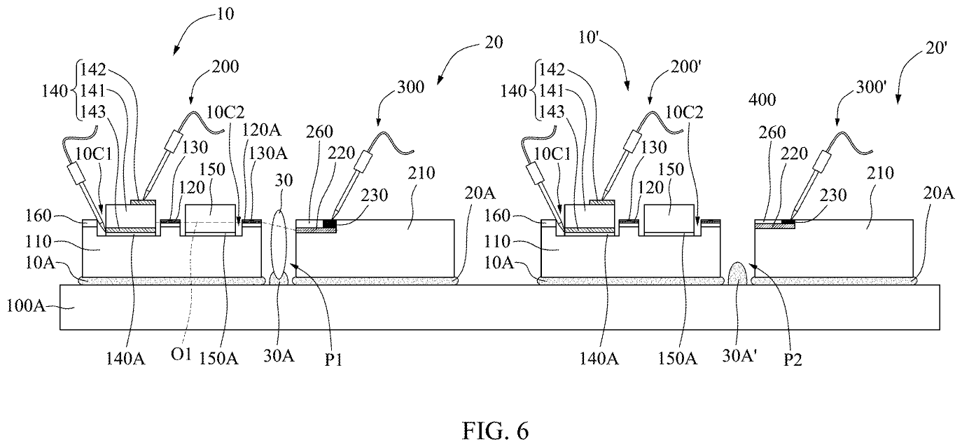

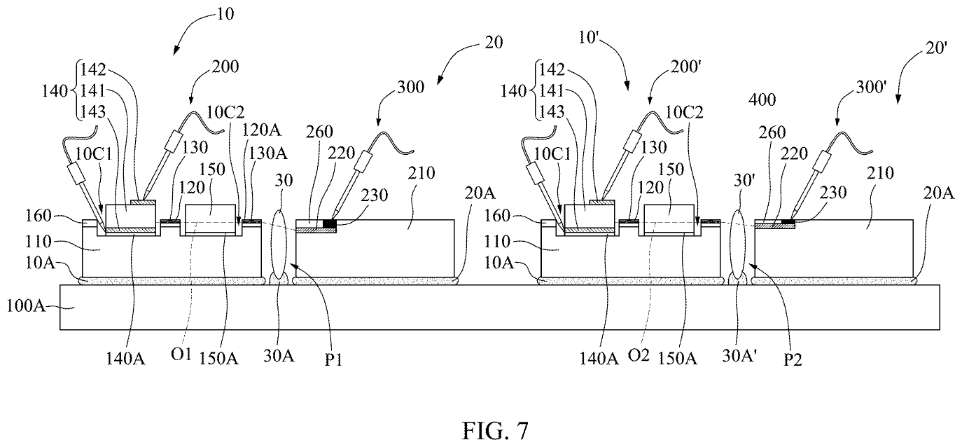

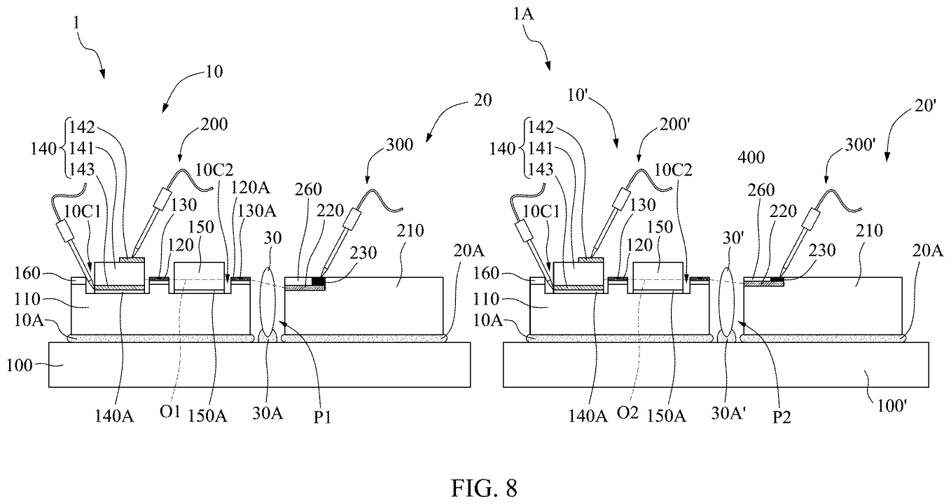

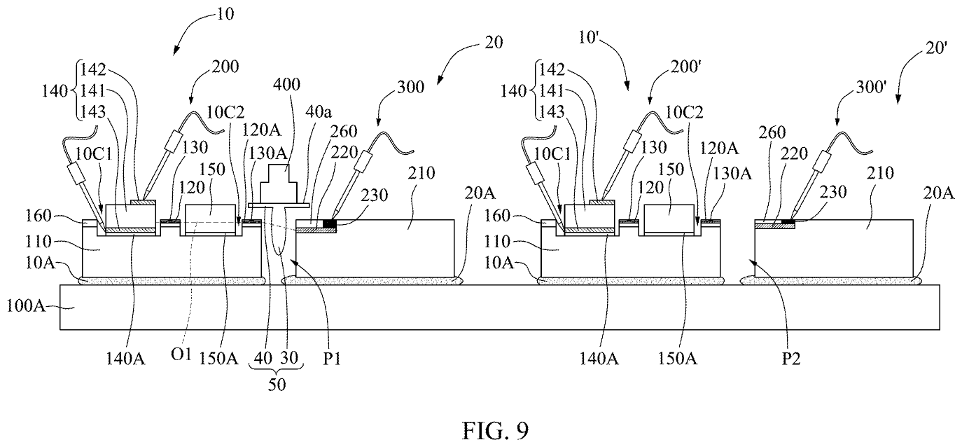

FIG. 9, FIG. 10, FIG. 11, FIG. 12, and FIG. 13 illustrate various stages of an example of a method for manufacturing an optoelectronic structure in accordance with some arrangements of the present disclosure. To streamline the description and for the convenience of comparison between various arrangements of the present disclosure, similar components in the following examples bear the same numerals, and may not be redundantly described.

Referring to FIG. 9, operations similar to those illustrated in FIGS. 1A-1B may be performed to provide a substrate 100A and light source modules 10 and 10′ and photonic components 20 and 20′, and operations similar to those illustrated in FIGS. 2-3 may be performed to provide a lens structure 50 and perform an active alignment between the waveguide 120A of the light source module 10 and the photonic component 20. In some arrangements, the active alignment includes aligning (or actively aligning) an optical path O1 between the waveguide 120A and the photonic component 20 by moving the lens structure 50 to a unit specific position P1. In some arrangements, a planarization operation may be performed on upper surfaces of the light source modules 10 and 10′ and the photonic components 20 and 20′, such that the upper surfaces of the light source modules 10 and 10′ and the photonic components 20 and 20′ may be substantially coplanar.

In some arrangements, the lens structure 50 includes a supporting plate 40 and a lens 30 connected to the supporting plate 40. In some arrangements, the lens 30 is supported by the supporting plate 40. The lens structure 50 (or the supporting plate 40) has a planar upper surface 40a configured to attach to the vacuum suction mechanism 400. In some arrangements, the lens structure 50 is a single-piece lens element. In some arrangements, the supporting plate 40 and the lens 30 are integrally formed as a monolithic lens structure 50.

Referring to FIG. 10, operations similar to those illustrated in FIG. 5 may be performed to provide a lens structure 50′ and perform an active alignment between the waveguide 120A of the light source module 10′ and the photonic component 20′. In some arrangements, after the unit specific position P1 of the lens structure 50 is determined, the lens structure 50 may be removed away from the unit specific position P1. In some arrangements, the active alignment includes aligning (or actively aligning) an optical path O2 between the waveguide 120A and the photonic component 20′ by moving the lens structure 50′ to a unit specific position P2.

In some arrangements, the lens structure 50′ includes a supporting plate 40′ and a lens 30′ connected to the supporting plate 40′. The lens structure 50′ (or the supporting plate 40′) has a planar upper surface 40a′ configured to attach to the vacuum suction mechanism 400. In some arrangements, the lens structure 50′ is a single-piece lens element. In some arrangements, the supporting plate 40′ and the lens 30′ are integrally formed as a monolithic lens structure 50′.

Referring to FIG. 11, after the unit specific position P2 of the lens structure 50′ is determined, the lens structure 50′ may be removed away from the unit specific position P2. In some arrangements, adhesive elements 60 and 60A are then disposed (or positioned) adjacent to the unit specific position P1. In some arrangements, the positions of the adhesive elements 60 and 60A are determined according to the unit specific position P1. In some arrangements, adhesive elements 60′ and 60A′ are then disposed (or positioned) adjacent to the unit specific position P2. In some arrangements, the positions of the adhesive elements 60′ and 60A′ are determined according to the unit specific position P2. The adhesive elements 60, 60A, 60′, and 60A′ may be or include photosensitive glues.

In some arrangements, at least two or more of the adhesive elements (e.g., the adhesive elements 60, 60A, 60′, and 60A′) may have different heights, thicknesses, and/or volumes. According to some arrangements of the present disclosure, the differences in the heights, thicknesses, and/or volumes between the adhesive elements can provide different predetermined spaces or gaps between the lens structures and the upper surfaces of the light source modules, and also can provide different predetermined spaces or gaps between the lens structures and the upper surfaces of the photonic components. For example, the adhesive element having a relatively large height, thickness, and/or volume can provide a relatively large space or gap between the lens structure and the light source/the photonic component. Therefore, the shifts in the position of the lens structure can be compensated, the processing window can be enlarged, and the flexibility of determination of the unit specific position can be increased.

Referring to FIG. 12, the lens structure 50 may be disposed on or affixed to the unit specific position P1, and the lens structure 50′ may be disposed on or affixed to the unit specific position P2. Similar to the operations illustrated in FIGS. 5 and 7 for disposing the lenses 30 and 30′ on or affixing the lenses 30 and 30′ to the adhesive elements 30A and 30A′, the lens structures 50 and 50′ may be disposed on (or movably affixed at) the respective unit specific positions P1 and P2, and then post-alignments may be further performed by adjusting or moving the lens structures 50 and 50′ to ensure an optimum optical alignment between the light source module 10 (e.g., the waveguide 120A) and the photonic component 20 through the lens structure 50 and an optimum optical alignment between the light source module 10′ (e.g., the waveguide 120A) and the photonic component 20′ through the lens structure 50′.

In some arrangements, the post-alignment of the light source module 10 with the photonic component 20 may be performed by moving the lens structure 50 with the vacuum suction mechanism 400, the vacuum suction mechanism 400 is then removed from the lens structure 50 after the post-alignment is completed, and then the post-alignment of the light source module 10′ with the photonic component 20′ may be performed by moving the lens structure 50′ with the vacuum suction mechanism 400. In some arrangements, the post-alignment of the light source module 10 with the photonic component 20 and the post-alignment of light source module 10′ with the photonic component 20′ may be performed simultaneously or in the same operation by moving the lens structures 50 and 50′ with vacuum suction mechanisms 400 and 400A, respectively.

Referring to FIG. 13, operations similar to those illustrated in FIG. 8 may be performed to dispose or permanently affix the lens structures 50 and 50′ at the unit specific positions P1 and P2, respectively. In some arrangements, the adhesive elements 60, 60A, 60′, and 60A′ may be cured (e.g., by UV) to attach or permanently affix the lens structures 50 and 50′ at the unit specific positions P1 and P2, respectively.

In some arrangements, a singulation operation may be performed on the substrate 100A to form a singulated structure (e.g., an optoelectronic structure 1B) including the light source module 10, the photonic component 20, and the lens structure 50 on a substrate 100, and a singulated structure (e.g., an optoelectronic structure 1C) including the light source module 10′, the photonic component 20′, and the lens structure 50′ on a substrate 100′.

According to some arrangements of the present disclosure, the lens structure includes a supporting plate that is close to the upper surfaces of the light source module and the photonic component in the beginning of the active alignment process. With the arrangement, the supporting plate may approach and be disposed on the upper surfaces of the light source module and the photonic component in the active alignment process. That is, such arrangement may serve as a pre-alignment vertically. Accordingly, the moving distance of the lens structure along a vertical direction (or along a vertical axis) may be reduced, and the time for adjusting the position of the lens structure along a vertical direction (or along a vertical axis) may be reduced.

In addition, according to some arrangements of the present disclosure, the lens structure is disposed on or affixed to upper surfaces of the light source module and the photonic component instead of attached to the substrate. For example, the lens structure is disposed over and spaced apart from the substrate. Therefore, the lens structure is free from contacting or connecting to the substrate, and particles or the adhesive elements that connect the light source module and/or the photonic component to the substrate may be disposed or extend over a region of the substrate that is under the lens structure without adversely influencing the arrangement of the lens structure. Moreover, since the lens structure is not disposed on or connected to a portion of the substrate, the lens structure can be prevented from being shift in its position by contacting the particles or the adhesive elements on the substrate. Therefore, the process can be simplified, and the yield can be increased.

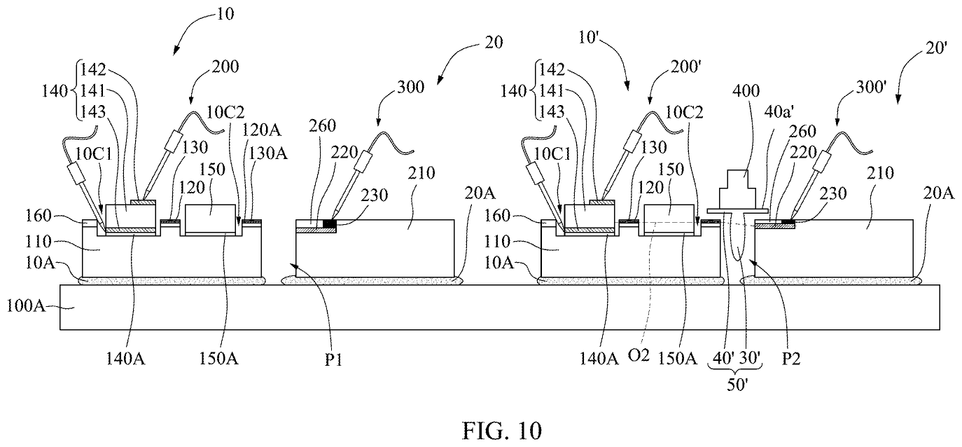

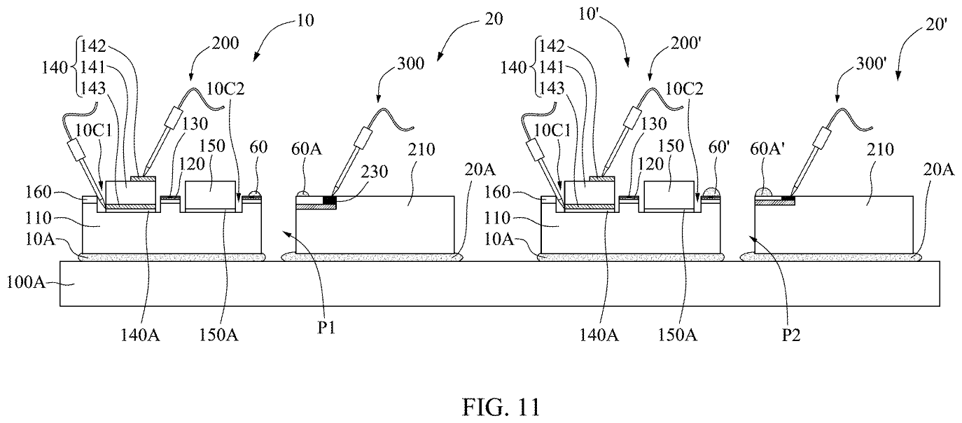

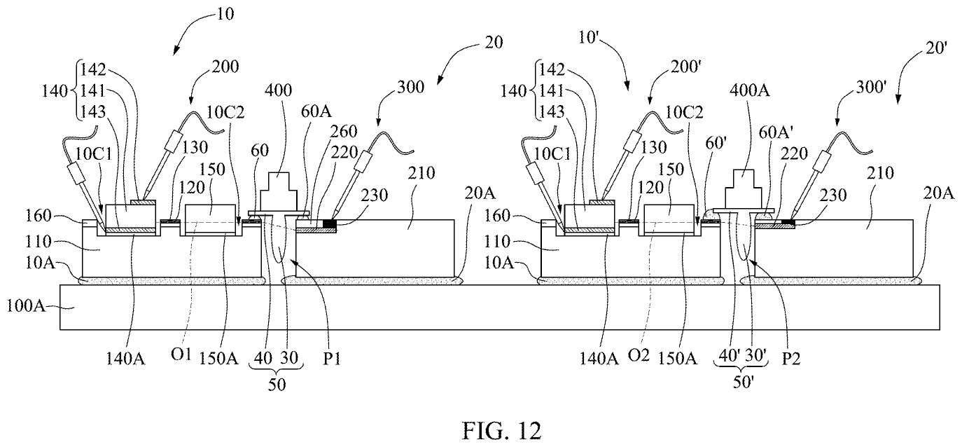

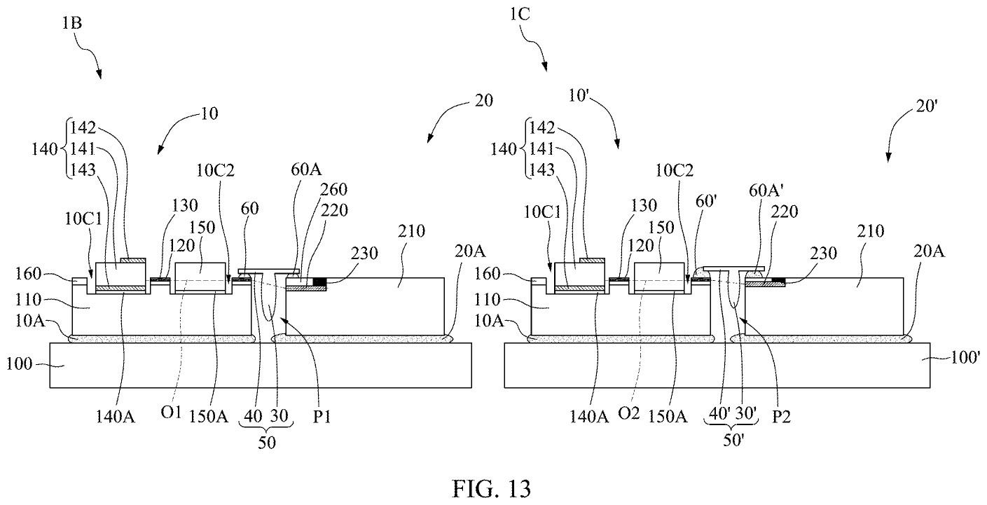

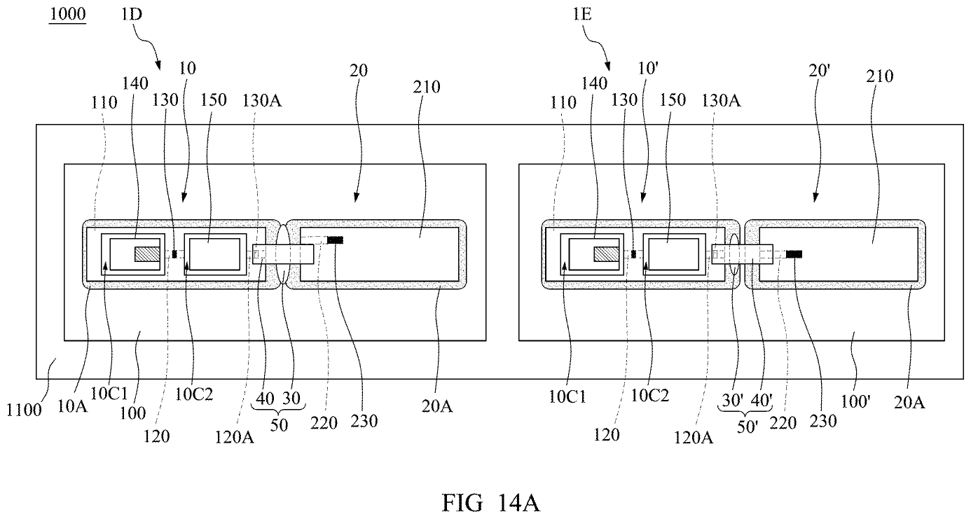

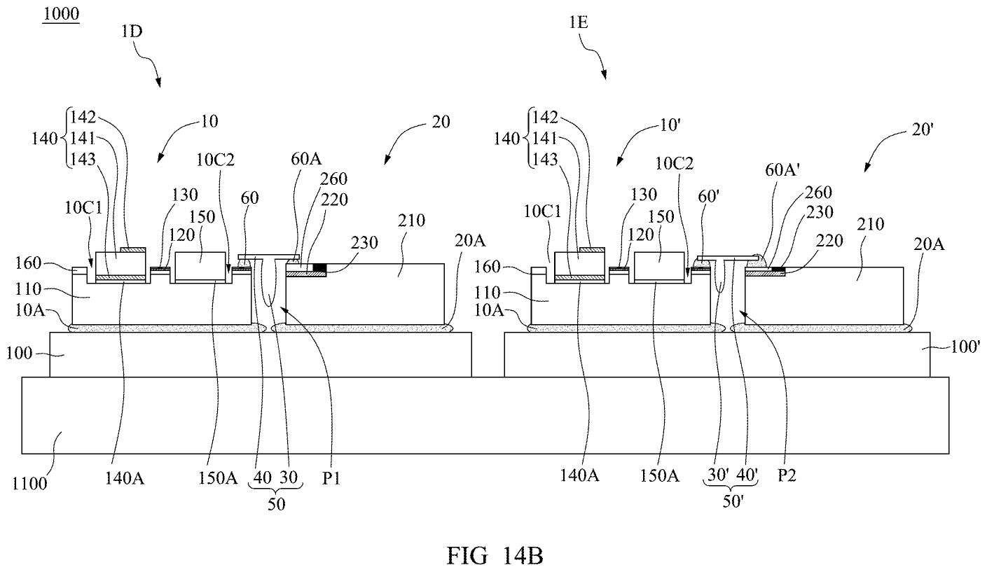

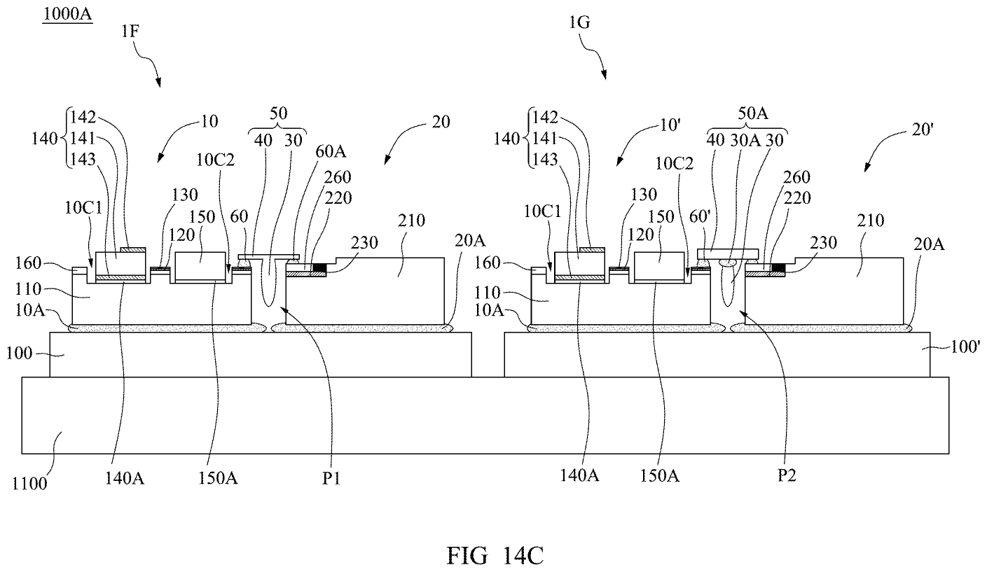

FIG. 14A is a top view of a package structure 1000 in accordance with some arrangements of the present disclosure, and FIG. 14B is a cross-section of a portion of a package structure 1000 in accordance with some arrangements of the present disclosure. FIG. 14B is a cross-section of the structure shown in FIG. 14A. The package structure 1000 includes a carrier 1100 and optoelectronic structures 1D and 1E over the carrier 1100.

In some arrangements, the optoelectronic structures 1D and 1E include different structures. In some arrangements, upper surfaces of the light source module 10 and the photonic component 20 are at different elevations. In some arrangements, the waveguides 220 of the optoelectronic structures 1D and 1E are at different elevations. In some arrangements, the lens structure 50 of the optoelectronic structure 1D and the lens structure 50′ of the optoelectronic structure 1D are different. In some arrangements, the lens structure 50 (or the optical alignment component) is disposed at a unit specific position P1 related to the light source module 10 and the photonic component 20, and the lens structure 50′ (or the optical alignment component) is disposed at a unit specific position P2 related to the light source module 10′ and the photonic component 20′. In some arrangements, the unit specific positions P1 and P2 are different. In some arrangements, each of the unit specific positions P1 and P2 includes an elevation of the lens structure (or the optical alignment component) with respect to the carrier, a distance between the lens structure (or the optical alignment component) and the carrier, a distance between the lens structure (or the optical alignment component) and the light source module, a distance between the lens structure (or the optical alignment component) and the photonic component, a difference in elevations of the lens structure (or the optical alignment component) and the light source module, a difference in elevations of the lens structure (or the optical alignment component) and the photonic component, and any combination thereof.

In some arrangements, the lens structure 50 includes a supporting plate 40 and a lens 30 connected to the supporting plate 40, and the lens structure 50′ includes a supporting plate 40′ and a lens 30′ connected to the supporting plate 40′. In some arrangements, the supporting plate 40 is connected to the light source module 10 and the photonic component 20 through the adhesive elements 60 and 60A, and the supporting plate 40′ is connected to the light source module 10′ and the photonic component 20′ through the adhesive elements 60′ and 60A′. In some arrangements, the lens 30 of the lens structure 50 is configured to define an optical path between the waveguide 120A of the light source module 10 and the waveguide 220 of the photonic component 20. In some arrangements, the lens 30′ of the lens structure 50′ is configured to define an optical path between the waveguide 120A of the light source module 10′ and the waveguide 220 of the photonic component 20′. In some arrangements, the lens 30 is spaced apart from the substrate 100, and the lens 30′ is spaced apart from the substrate 100′. In some arrangements, heights or thicknesses of the lenses 30 and 30′ are different. In some arrangements, the lens 30′ is closer to the light source module 10′ than to the photonic component 20′. In some arrangements, the adhesive element 60A covers a portion of an upper surface of the supporting plate 40′.

FIG. 14C is a cross-section of a portion of a package structure 1000A in accordance with some arrangements of the present disclosure. The package structure 1000A may include optoelectronic structures 1F and 1G. The structure illustrated in FIG. 14C is similar to that in FIGS. 14A-14B, with differences therebetween as follows.

In some arrangements, the optoelectronic structures 1F and 1G include different structures. In some arrangements, the photonic component 20 has a recess recessed from an upper surface of the photonic component 20. In some arrangements, the adhesive elements 60 and 60A have different thicknesses. In some arrangements, the optoelectronic structure 1G includes a lens structure 50A including a lens 30, a supporting plate 40, and an adhesive element 30A connecting the lens 30 to the supporting plate 40. In some arrangements, the supporting plate 40 is made of or includes a different from that of the lens 30. In some arrangements, the supporting plate 40 includes a non-transparent material. In some arrangements, the supporting plate 40 includes an organic material (e.g., a plastic plate), an inorganic material (e.g., a silicon-based layer or a ceramic plate), a metal material (e.g., a metal plate), or a combination thereof.

According to some arrangements of the present disclosure, the photonic component 20 having a recess for accommodating and attaching to the adhesive element 60A, and thus the size of the optoelectronic structure in a vertical direction can be reduced. In addition, according to some arrangements of the present disclosure, the supporting plate 40 that is formed separately and then connected to the lens 30 by the adhesive element 30A, such that the processing flexibility is increased, and the selection of the material, the shape, and/or the structure of the supporting plate 40 can be relatively flexible according to actual applications.

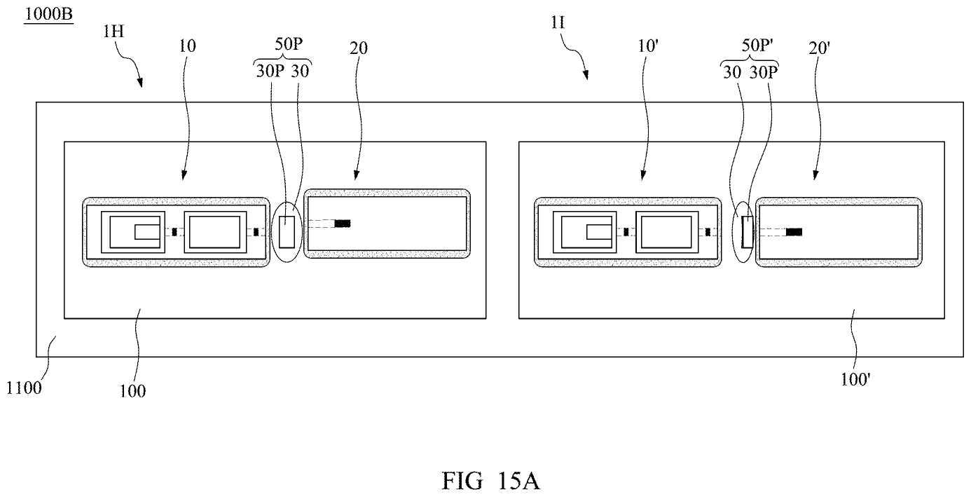

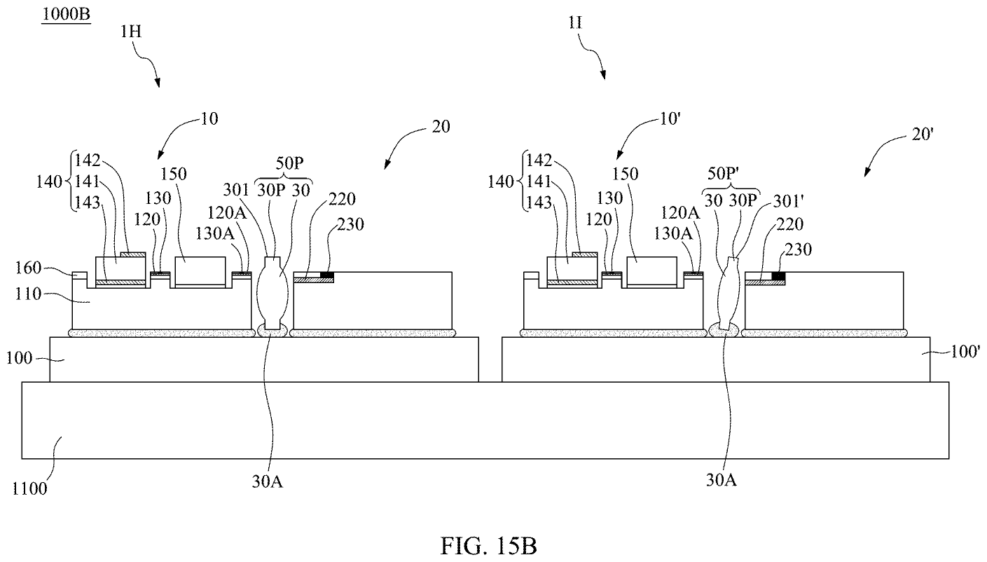

FIG. 15A is a top view of a package structure 1000B in accordance with some arrangements of the present disclosure, and FIG. 15B is a cross-section of a portion of a package structure 1000B in accordance with some arrangements of the present disclosure. The package structure 1000B may include optoelectronic structures 1H and 1I. The structure illustrated in FIGS. 15A-15B is similar to that in FIGS. 14A-14B or in FIG. 14C, with differences therebetween as follows.

In some arrangements, the optoelectronic structure 1H includes a lens structure 50P including a lens 30 and a protrusion 30P having a planar upper surface 301 configured to attach to a vacuum suction mechanism, and the optoelectronic structure 1I includes a lens structure 50P′ including a lens 30 and a protrusion 30P having a planar upper surface 301′ configured to attach to a vacuum suction mechanism. In some arrangements, the lens structure 50P′ tilts toward the photonic component 20′.

According to some arrangements of the present disclosure, the planar upper of the lens 30 configured to be attached to a vacuum suction mechanism is advantageous to picking-up and adjusting or moving the lens 30 in the active alignment process. Therefore, the structure of the lens 30 does not require a complicated design for connection with a pick-up device in the alignment process, and the lens 30 can remain relatively small and light, which facilitates the movement of the lens 30 in the active alignment process.

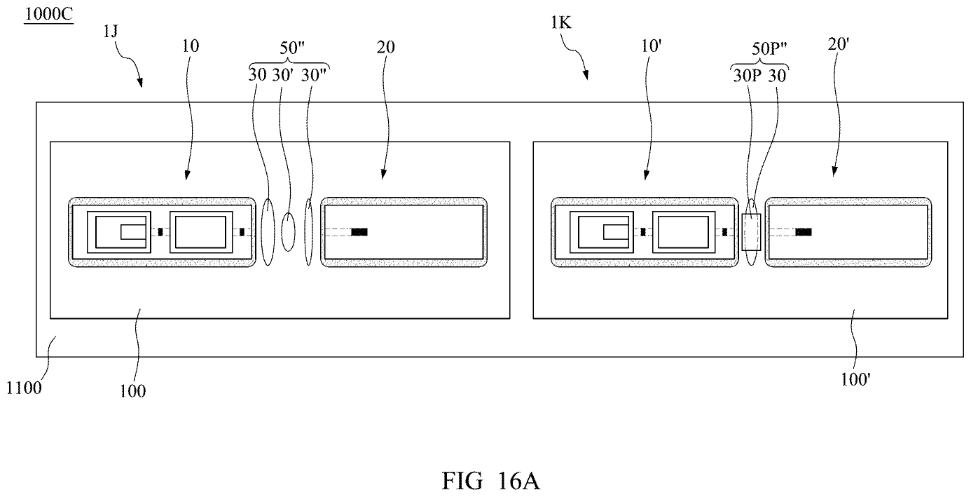

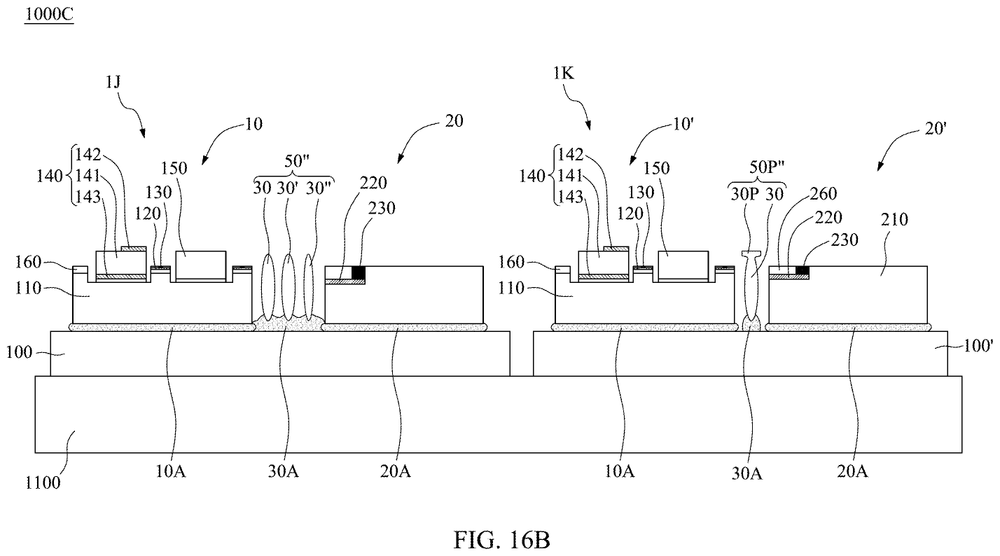

FIG. 16A is a top view of a package structure 1000C in accordance with some arrangements of the present disclosure, and FIG. 16B is a cross-section of a portion of a package structure 1000C in accordance with some arrangements of the present disclosure. The package structure 1000C may include optoelectronic structures 1J and 1K. The structure illustrated in FIGS. 16A-16B is similar to that in FIGS. 14A-14B, in FIG. 14C, or in FIGS. 15A-15B, with differences therebetween as follows.

In some arrangements, the optoelectronic structure 1J includes a lens structure 50″ including a lens array (e.g., lenses 30, 30′, and 30″). The lenses 30, 30′, and 30″ may have different shapes or structures. In some arrangements, the lenses 30, 30′ and 30″ are all connected to the substrate 100 by a single-piece adhesive element 30A. The lenses 30, 30′ and 30″ may have planar upper surfaces (not shown). In some arrangements, the adhesive element 30A may contact a portion of the adhesive element 10A and a portion of the adhesive element 20A. In some arrangements, the optoelectronic structure 1K includes a lens structure 50P″ including a lens 30 and a protrusion 30P having a planar upper surface configured to attach to a vacuum suction mechanism. In some arrangements, a width of the protrusion 30P is greater than a width of the lens 30.

According to some arrangements of the present disclosure, the lenses 30, 30′ and 30″ are all connected to the substrate 100 by a single-piece adhesive element 30A, such that the space between the light source module 10 and the photonic component 20 can be reduced while multiple lenses may be provided with an improved alignment. In addition, according to some arrangements of the present disclosure, the protrusion 30P is relatively wide compared to the lens 30, and thus the planar upper surface can be relatively large, which is further advantageous to picking-up and moving the lens structure 50P″ in the active alignment process.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to ±4%, less than or equal to ±3%, less than or equal to ±2%, less than or equal to ±1%, less than or equal to ±0.5%, less than or equal to =0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to =0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method for manufacturing an optoelectronic structure, comprising:
providing a substrate and a light source module and a photonic component over the substrate; and
adjusting a lens structure to a unit specific position related to the substrate to couple an optical signal from the light source module to the photonic component.

2. The method as claimed in claim 1, further comprising:
determining that the lens structure is at the unit specific position when the optical signal being monitored reaches a predetermined optimization threshold.

3. The method as claimed in claim 2, wherein the predetermined optimization threshold comprises a predetermined intensity, a predetermined pattern, a predetermined intensity distribution, a predetermined signal-to-noise (S/N) ratio, or any combination thereof.

4. The method as claimed in claim 1, further comprising:
disposing an adhesive element adjacent to the unit specific position.

5. The method as claimed in claim 4, further comprising:
aligning the lens structure to the unit specific position and connected to the adhesive element.

6. The method as claimed in claim 5, further comprising:
curing the adhesive element.

7. The method as claimed in claim 1, further comprising:
attaching a planar upper surface of the lens structure to a vacuum suction mechanism; and
adjusting a position of the vacuum suction mechanism to adjust the lens structure.

8. The method as claimed in claim 1, wherein adjusting the lens structure comprises moving the lens structure without moving positions of the light source module and the photonic component after providing the light source module and the photonic component over the substrate without turning on the light source module.

9. A method for manufacturing an optoelectronic structure, comprising:
providing a substrate, and a first light source module, a first photonic component, a second light source module, and a second photonic component over the substrate;
actively aligning the first light source module with the first photonic component by moving a first lens structure to a first unit specific position related to the first photonic component; and
actively aligning the second light source module with the second photonic component by moving a second lens structure to a second unit specific position related to the second photonic component.

10. The method as claimed in claim 9, wherein the first unit specific position related to the first photonic component is different from the second unit specific position related to the second photonic component.

11. The method as claimed in claim 9, further comprising:
curing a first adhesive element and a second adhesive element to affix the first lens structure and the second lens structure to the first unit specific position and the second unit specific position, respectively, in a same operation.

12. A package structure, comprising:
an optoelectronic structure comprising a first optical component, a second optical component, and an optical alignment component configured to define an optical path between the first optical component and the second optical component,
wherein the optical alignment component is disposed at a unit specific position related to the first optical component and the second optical component.

13. The package structure as claimed in claim 12, wherein the optical alignment component comprises:
a supporting plate connected to the first optical component and the second optical component; and
a lens supported by the supporting plate and configured to define the optical path between the first optical component and the second optical component.

14. The package structure as claimed in claim 13, wherein the optoelectronic structure further comprises a substrate, the first optical component and the second optical component are disposed over the substrate, and the lens is spaced apart from the substrate.

15. The package structure as claimed in claim 12, wherein the optoelectronic structure further comprises a substrate, the first optical component and the second optical component are disposed over the substrate, and the optical alignment component comprises a lens having a planar upper surface and connected to the substrate by an adhesive element.

16. The package structure as claimed in claim 12, wherein the optoelectronic structure further comprises a substrate, the first optical component and the second optical component are affixed to the substrate, and the optical alignment component comprises a lens array.

17. The package structure as claimed in claim 12, further comprising a carrier and a plurality of the optoelectronic structures over the carrier, wherein at least two of the unit specific positions of the optoelectronic structures are different.

18. The package structure as claimed in claim 17, wherein each of the unit specific positions comprises an elevation of the optical alignment component with respect to the carrier, a distance between the optical alignment component and the carrier, a distance between the optical alignment component and the first optical component, a distance between the optical alignment component and the second optical component, a difference in elevations of the optical alignment component and the first optical component, a difference in elevations of the optical alignment component and the second optical component, and any combination thereof.

19. The package structure as claimed in claim 18, wherein at least two of the first optical components each comprises a first waveguide, a light source optically coupled to the first waveguide, and an active optical element passively aligned by the first waveguide.

20. The package structure as claimed in claim 19, wherein at least two of the optical alignment components of the optoelectronic structures comprise different structures.
